(19) United States
(12) Patent Application Publication
(10) Pub. No.: US 2015/0109007 A1
(43) Pub. Date: Apr. 23, 2015

(54) DIFFERENTIAL AMPLIFIER AND ELECTRODE FOR MEASURING A BIOPOTENTIAL

(71) Applicant: George Townsend, Sault Ste. Marie (CA)

(72) Inventor: George Townsend, Sault Ste. Marie (CA)

(21) Appl. No.: 14/388,725

(22) PCT Filed: Mar. 29, 2012
(86) PCT No.: PCT/CA2012/000278

§ 371 Date: Dec. 18, 2014

(51) Int. Cl. G01R 1/30; G01R 1/20; H03F 3/45

(52) U.S. Cl. CPC G01R 1/30; H03F 3/45076; G01R 1/203; H03F 2203/45138; H03F 2203/45244
USPC 324/692; 330/252; 330/261

(57) ABSTRACT

A differential amplifier is described that provides a high common mode rejection ration (CMRR) without requiring the use of precisely matched components. One variation employs a method of noise reduction to increase the SNR of the device. The differential amplifier may be used in an apparatus for measuring biopotentials of a patient, such as an electrode for measuring brain activity. The electrodes can communicate the measured biopotentials with a remote system for further processing, while providing electrical isolation to the patient.

### TECHNICAL FIELD

The current description relates to an electrode for measuring a biopotential and in particular to an electrode using a differential amplifier of un-matched components that provides a large common mode rejection ratio.

### BACKGROUND

Acquiring biopotential signals, such as brain signals for an electroencephalogram, for research or medical diagnosis involves either measuring the difference in electrical potential between two closely spaced electrodes about an area of interest, often referred to as bipolar EEG, or measuring the difference between an electrode directly over an area of interest and a reference electrode over a relatively inactive area such as a mastoid or on the forehead, often referred to as, monopolar EEG. In both cases, the measured biopotential signal is determined from the difference in electrical potential between a reference signal and a desired signal. The difference between the reference and desired signals may be determined using a differential amplifier.

The biopotential signal to be measured is typically a relatively small signal and may be overwhelmed by electrical noise, such as electrical noise from a 60 Hz power line, that is common to both the reference signal and the desired signal. The electrical noise common to both signals may be several orders of magnitude larger than the biopotential signal being measured. As such, the differential amplifier must very accurately subtract the reference signal from the desired signal so that the relatively huge common component will cancel out.

In order to provide a differential amplifier that is capable of precisely rejecting the electrical noise common to both signals, the components, or more particularly the values of the components such as the resistance of resistors, of the differential amplifier must be critically matched to each other's values. At the chip level, this may involve the laser trimming of resistors to achieve the precise values required, although other techniques are possible. Despite the best efforts, changes in component values after construction are possible which may upset the balance of the differential amplifier and result in less common noise being rejected.

Further, when measuring biopotential signals of a patient, electrical isolation between the patient and the recording equipment is required for safety. The required electrical isolation may be provided by converting the measured biopotential signal to an optical signal which may be transmitted to the recording equipment for further processing. Typically, the conversion of the biopotential signal to an optical signal is done after amplifying and filtering the signal at the patient side. As such, amplification and filtering components are required at the electrode in order to properly convert the measured biopotential signal. In order to provide the required electrical isolation at the patient, these amplification and filtering components are generally powered by batteries. However, the power requirements of the amplification and filtering stages may drain the batteries relatively quickly, requiring the batteries be replaced.

It is desirable to have an electrode for measuring biopotentials of a patient that overcomes or mitigates one or more of the problems with current electrodes.

### SUMMARY

In accordance with the present disclosure there is provided an apparatus for measuring potentials on a body surface comprising: a first contact area for contacting the body surface and providing a first signal; a second contact area for contacting the body surface and providing a second signal; a differential amplifier for providing an output signal proportional to the difference between the first signal and the second signal, the differential amplifier comprising: a first OP-AMP having a first input, second input and an output, the first input coupled to the first signal and the second input coupled to the output; a second OP-AMP having a first input, second input and an output, the first input coupled to the second signal and the second input coupled to the output; and a resistor connected between the output of the first OP-AMP and the output of the second OP-AMP, wherein the output signal is proportional to the current through the resistor.

In accordance with the present disclosure there is further provided a system for measuring biopotentials of a patient, the system comprising: a plurality of apparatuses for measuring biopotentials; and a remote processing unit for receiving signals corresponding to the output signals of the respective apparatuses, the remote processing unit further processing the received signals. Each of the plurality of apparatuses comprises a first contact area for contacting the body surface and providing a first signal; a second contact area for contacting the body surface and providing a second signal; a differential amplifier for providing an output signal proportional to the difference between the first signal and the second signal, the differential amplifier comprising: a first OP-AMP having a first input, second input and an output, the first input coupled to the first signal and the second input coupled to the output; a second OP-AMP having a first input, second input and an output, the first input coupled to the second signal and the second input coupled to the output; and a resistor connected between the output of the first OP-AMP and the output of the second OP-AMP, wherein the output signal is proportional to the current through the resistor.

In accordance with the present disclosure there is further provided a differential amplifier for providing an output signal proportional to a difference between a first signal and a second signal, the differential amplifier comprising at least one individual differential amplifiers comprising: a first OP-AMP having a first input, second input and an output, the first input coupled to the first signal and the second input coupled to the output; a second OP-AMP having a first input, second input and an output, the first input coupled to the second signal and the second input coupled to the output; and a resistor connected between the output of the first OP-AMP and the output of the second OP-AMP, wherein the output signal is proportional to the current through the resistor.

### BRIEF DESCRIPTION OF THE DRAWINGS

Further features and advantages of the present disclosure will become apparent from the following detailed description, taken in combination with the appended drawings, in which:

FIG. 1 depicts a schematic of an embodiment of a differential amplifier for use in an electrode for measuring a biopotential;

FIG. 2 depicts a schematic of a further embodiment of a differential amplifier for use in an electrode for measuring a biopotential;

FIG. 3 depicts a schematic of a further embodiment of a differential amplifier for use in an electrode for measuring a biopotential;

FIG. 4 depicts a schematic of a further embodiment of a differential amplifier for use in an electrode for measuring a biopotential;

FIG. 5 depicts a schematic of a further embodiment of a differential amplifier for use in an electrode for measuring a biopotential;

FIG. 6 depicts a schematic of a further embodiment of a differential amplifier for use in an electrode for measuring a biopotential;

FIG. 7 depicts a schematic of an embodiment of a multi-sample differential amplifier for use in an electrode for measuring a biopotential;

FIG. 8 depicts a schematic of components of an electrode for use in measuring a biopotential;

FIG. 9 depicts a schematic of contact areas of an electrode for measuring a biopotential; and

FIG. 10 depicts in a block diagram a system for measuring biopotentials.

### DETAILED DESCRIPTION

A differential amplifier for use in an electrode for measuring biopotentials is described further below. The electrode with the differential amplifier may be used as an electrode in an electroencephalogram (EEG) system. The electrode described provides electrical isolation of the patient and an extremely high degree of common mode rejection while requiring absolutely no matching or balancing of component values. The described electrode uses relatively few components and can be powered efficiently with batteries. The differential amplifier utilizes two operational amplifiers (OP-AMPs) arranged such that one of the OP-AMPs acts as a current source, while the other OP-AMP acts as a current sink. A resistor is coupled between the two OP-AMPs and the current flowing through the resistor is proportional to a difference between a reference signal and a desired signal. Advantageously, the arrangement described provides a high common mode rejection ratio (CMRR), while eliminating the need to have precisely matched component values.

The differential amplifiers described herein do not require precisely matched component values while still providing a high CMRR. Further, the differential amplifier described provides a high degree of electrical isolation for the patient by electrically decoupling the electrode from the amplification and filtering stages as well as the recording and processing equipment. The filtering and amplification may be done at a non-patient side of the system allowing the amplification and filtering, as well as any further processing and recording, to be safely powered without the use of batteries. As a result, only the measurement electrode is battery powered minimizing the power requirements of the electrode and so extending its battery life.

As described further herein, the differential amplifier is based on unity gain amplifiers. The use of unity gain amplifiers do not rely upon a voltage divider between the input and feedback path, and as such, are not as reliant upon precise component value matching as non-unity gain amplifiers. As described further, the differential amplifier employs two OP-AMPs having their outputs coupled together through a resistor to provide an output signal. One of the OP-AMPs has an input connected to the desired signal, while the other OP-AMP has an input connected to the reference signal. As a result of the described configuration, the current flowing through the resistor, as well as the voltage across the resistor, is proportional to the differential signal between the reference and desired signals. Unity gain amplifiers are utilized as it is easy to obtain highly accurate unity gain amplifiers, resulting in the current flowing through the described resistor being proportional to the difference between the two signals, as opposed to using non-unity gain amplifiers which would require the gain of each OP-AMP to be precisely matched in order to provide a current through the resistor that is proportional to the difference between the reference signal and the desired signal.

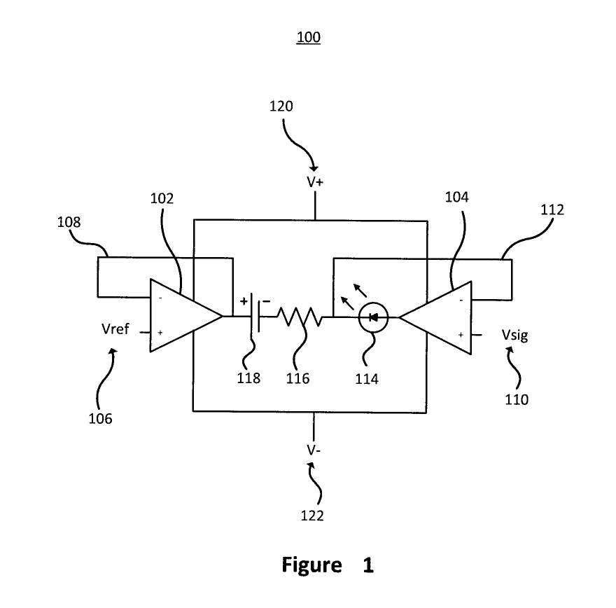

FIG. 1 depicts a schematic of an embodiment of a differential amplifier for use in an electrode for measuring a biopotential. The differential amplifier 100 converts the desired biopotential signal into a corresponding optical signal using a light emitting diode (LED) 114, which may be coupled to a remote processing computer or system for further amplification, filtering and processing of the signal. The biopotential signal is described herein as being transmitted to a remote processing system via an LED and fiber optic cable, which provides electrical isolation for the patient; however, it is contemplated that other means for transmitting the measured biopotential signal to the remote system while maintaining the desired electrical isolation are possible. For example it is possible to communicate the measured biopotential signal to the remote system using a radio frequency (RF) communication interface such as a WiFi™ interface, WiMax™ interface, ZigBee™ interface, BlueTooth™ interface or other wireless communication interface. Although various communication interfaces are contemplated, only the use of the LED interface is described further herein.

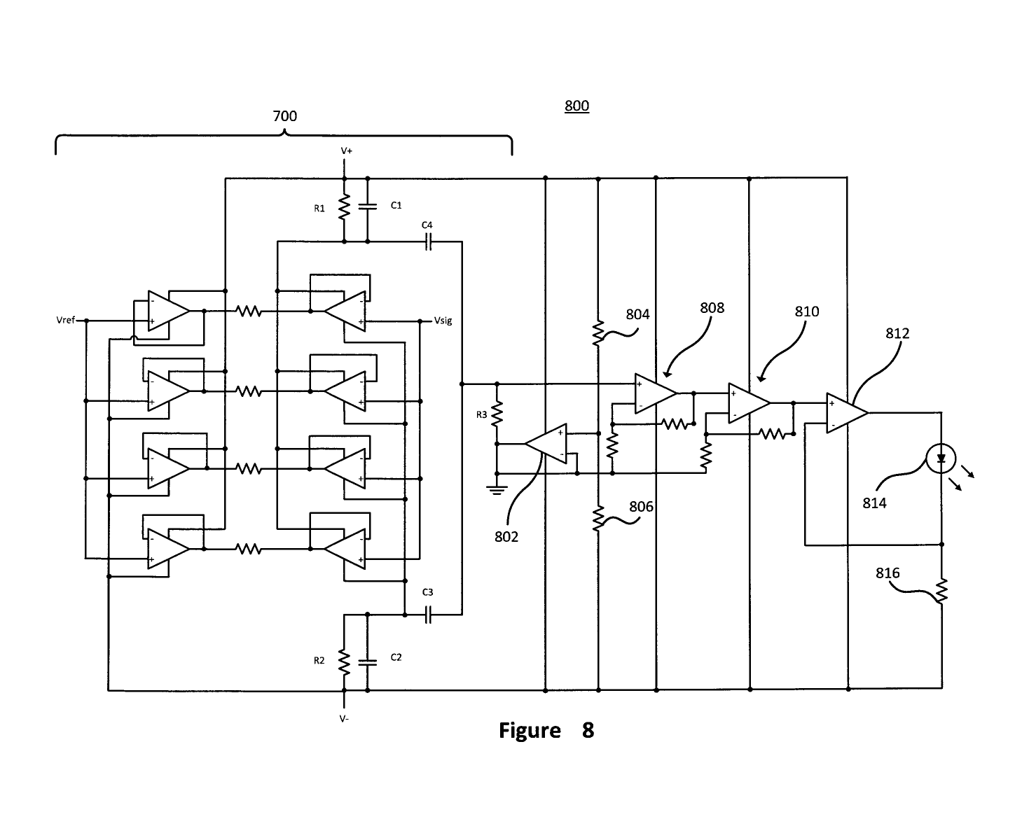

The differential amplifier 100 determines the difference between a desired signal (Vsig) 110 and a reference signal (Vref) 106 to light an LED 114 which emits light into a fiber optic cable (not shown) to a photo transistor (not shown) at a remote processing computer or system (not shown) where it is converted back into an electrical signal for further processing. Although not depicted in FIG. 1, it is contemplated that the desired signal (Vsig) 110 and the reference signal (Vref) 1006 are provided from contact areas of an electrode that are located in the same vicinity of each other. An illustrative embodiment of the contact areas of the electrode are described in further detail with regards to FIG. 8.

As is apparent from FIG. 1, the differential amplifier 100 comprises two unity gain OP-AMPs 102, 104 with their outputs coupled together through a resistor 116. One of the OP AMPs 102 has one of its inputs, namely the non-inverting input as depicted, coupled to the reference signal (Vref) 106, which is received from an appropriate contact area of the electrode when it is placed on a patient's head. The other input, namely the inverting input as depicted, of the OP-AMP 102 is coupled to the output of the OP-AMP 102 by a feedback path 108. As depicted in FIG. 1, the feedback path 108 directly connects the output of the OP-AMP 102 to the inverting input of the OP-AMP 102. Similarly, the other OP-AMP 104 has one of its inputs, namely the non-inverting input as depicted, coupled to the desired signal (Vsig) 110, which is received from an appropriate contact area of the electrode when it is placed on the patient's head. The other input, namely the inverting input as depicted, of the OP-AMP 104 is coupled to the output of the OP-AMP 104 by a feedback path 112. As depicted in FIG. 1, the feedback path 112 directly connects the output of the OP-AMP 104 to the inverting input of the OP-AMP 102. Further, as depicted, each OP-AMP receives power from a supply voltage (V+) 120, (V−) 122 which may be provided by a battery. For example V+/V− may be provided by a 6V battery, or other direct current (DC) power source. It is noted, that it is desirable to have V+ 120 and V− 122 be provided from a battery in order to provide the desired electrical isolation of the patient, however other power sources are possible for providing V+/V−, provided they are electrically isolated (such as inductively coupled, for example).

A resistor 116 is coupled between the outputs of the two OP-AMPs 102, 104. A current flows through the resistor 116 that is proportional to the difference between the desired signal (Vsig) 110 and the reference signal (Vref) 106. It is noted, that regardless of the voltage at the output of either of the OP-AMPs 102, 104, the presence of the battery 118 ensures that the OP-AMP feeding the anode of the LED will always be sourcing current while the other OP-AMP will always be sinking current, thereby allowing a current to flow through the LED and the resistor 116. As such, the current flowing through the resistor 116 will be proportional to the difference signal between the reference signal 106 and the desired signal 110.

As depicted in FIG. 1, a light emitting diode (LED) 114 is positioned between one of the OP-AMPs 104 and the feedback connection 108 for the OP-AMP 104. The input to the OP-AMP has a high impedance so that a negligible amount of current will flow through the feedback path 112 into the input of the OP-AMP 104. As such, the current flowing though the resistor 116 will also flow through the LED 114. Since the light intensity of an LED is proportional to the current through it, the light intensity will be proportional to the difference signal between the desired signal (Vsig) 110 and the reference signal (Vref) 106, allowing the desired biopotential signal, with any common noise rejected, to be transmitted by a fiber optic cable to a remote location for further processing, including amplification and filtering.

As will be appreciated, the intensity of the LED 114 is proportional to the intensity of the current flowing through the LED 114, assuming that the current is positive. However, it is possible that the current may also be negative based on the difference between the reference signal 106 and the desired signal 110. In order to allow the intensity to represent both positive and negative differences between the reference signal and the desired signal, a bias voltage is applied so that a positive current will always flow through the LED 114. As depicted the bias voltage may be provided by a battery 118 connected between the resistor 116 and the feedback path 108 connection of the OP-AMP 102.

It is noted that the implementation of FIG. 1 requires two separate power sources. The first power source provides the power V+/V− for operating the OP-AMPs while the second power source, namely the battery 118, provides the bias voltage to provide a bias current through the LED 114 to allow both positive and negative differences between the reference and desired signal to be converted to an optical signal. The bias current can be simply filtered from the transmitted signal at the receiving end.

The presence of the battery 118 and the fact that the potential differential signal from the two OP-AMPs should not exceed more than the battery voltage, since the differential signal may be relatively small in comparison to the battery voltage, ensures that the circuit of FIG. 1 will function as intended. Even accounting for large artifacts and DC offset due to the electrochemistry of the reaction between electrodes, gel, moisture, and skin, no more than several tenths of a volt should be expected as the difference between the reference signal 106 and the desired signal 110. As such, the circuit of FIG. 1 will maintain a forward bias on the LED 114 at all times, with a nominal 12 mA flowing through the LED 114. Furthermore, the current through the circuit is determined by the voltage drop across the resistor 116, which will be equal to the voltage of the battery 118 added to the difference between the desired signal voltage 110 and the reference signal voltage 106.

It is contemplated that various component values may be selected for the various components of the circuit 100. However, in order to provide a concrete example, it is assumed that the battery voltage is 2.0V, the resistor 116 is 200Ω, and the LED has a voltage drop of 2.0V. Further, it is assumed that the reference signal voltage (Vref) and the desired signal voltage (Vsig) vary from between −0.5V and +0.5V. The current flowing through the resistor 116 in the circuit of FIG. 1 in amperes is (2+Vsig−Vref)/200. Put another way, and expressed in milliamps, this is 10+5(Vsig−Vref). Therefore, 10 mA of “idling” current flows through the LED and increases or decreases, proportional to the difference between Vsig and Vref as required. As long as each of the OP-AMPs produces an output equal to its input, as provided by unity gain amplifiers, any common mode signals will be rejected by this arrangement. As described above, a unity gain OP-AMP can provide its input at its output with a high degree of accuracy. The bias current of 12 mA which keeps the LED 116 forward biased and lit at all times will represent a constant DC offset in the signal received at the photo transistor receiver at the remote processing system. This DC offset can be simply filtered out just as any unwanted DC offset is eliminated.

An electrode using the differential amplifier 100 described above will transport a clean difference signal with common mode noise removed via a fiber optic cable to a remote location for further signal conditioning where it cannot be influenced by electrical noise. The remote circuitry used for further signal processing does not suffer the same constraints of small size and low power consumption that apply to the electrode at the patient and therefore may be heavily shielded and protected from any further corruptions.

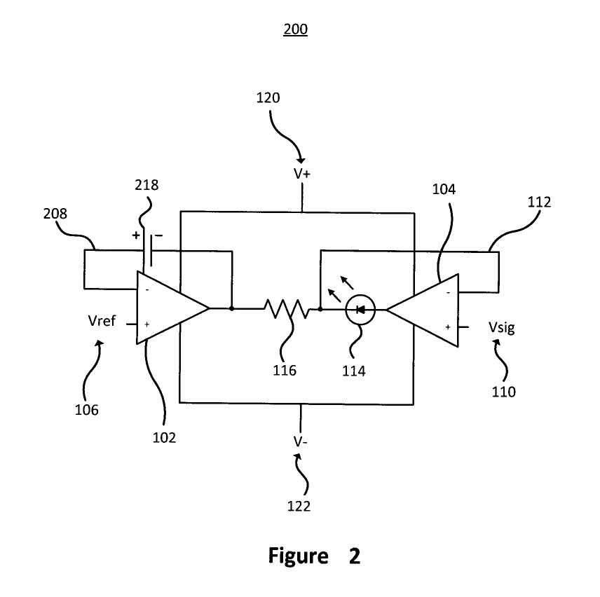

FIG. 2 depicts a schematic of a further embodiment of a differential amplifier for use in an electrode for measuring a biopotential. The differential amplifier 200 is substantially similar to the differential amplifier 100 and as such, only the differences are described in further detail. Rather than using a battery 118 coupled between the outputs of the two OP-AMPs as depicted in FIG. 1, the differential amplifier 200 comprises a battery 218 coupled in the feedback path 208 of one of the OP-AMPs. The battery 218 provides a bias voltage so that the LED 114 will always be forward biased, similar to the battery 118. However, since the inverting input of the OP-AMP has a high input impedance, the current drain on the battery will be very low in comparison to the battery 118, which is under the load of the LED. As such, placement of the battery 218 in the feedback path 208 allows a smaller battery to be used, while still providing a long battery life.

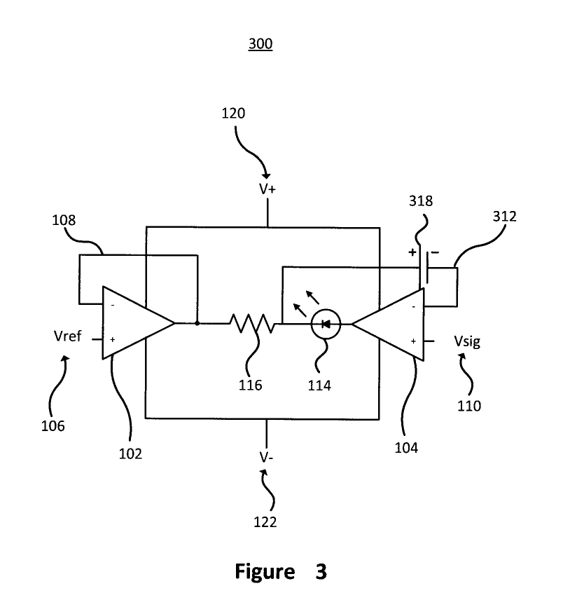

FIG. 3 depicts a schematic of a further embodiment of a differential amplifier for use in an electrode for measuring a biopotential. The differential amplifier 300 is substantially similar to the differential amplifier 200 and as such, only the differences are described in further detail. Rather than placing the battery 218 in the feedback path 208 of the OP-AMP 102 connected to the reference signal 106, the differential amplifier places a battery 318 in the feedback path 312 of the OP-AMP 104 connected to the desired signal 110. The battery 318 provides a bias voltage so that the LED 114 will always be forward biased, similar to the battery 218. As noted above with regards to FIG. 2, placement of the battery in the feedback path allows a smaller battery to be used, while still providing a long battery life.

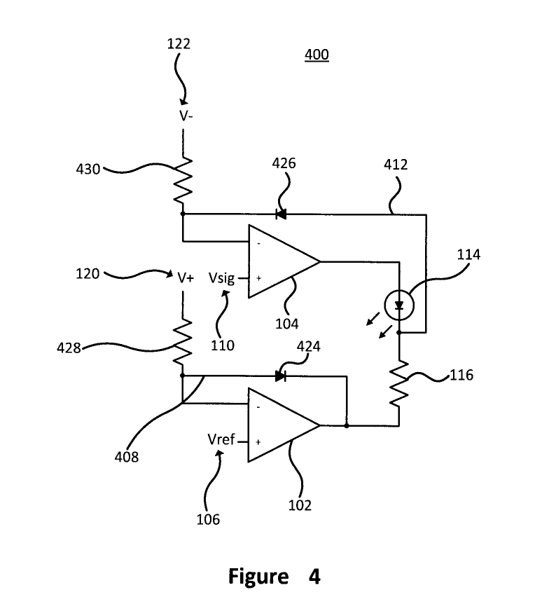

FIG. 4 depicts a schematic of a further embodiment of a differential amplifier for use in an electrode for measuring a biopotential. The differential amplifier 400 is substantially similar to the differential amplifier 100; however, rather than using a battery to provide a bias voltage, the differential amplifier 200 utilizes diodes in the respective feedback paths of the OP-AMPs to provide the bias voltage. Given that EEG systems on the subject side are battery powered for safety reasons, it may be practical to use the battery biasing arrangement of FIG. 1, however requiring an isolated battery reserved for use by each differential amplifier of the electrode may be undesirable. As such, the biasing can be provided by alternative means. For example, a relatively constant offset can be achieved by introducing a diode into the feedback path of the unity gain OP-AMPs and providing current via a resistor connected to an appropriate voltage source. Although the electrode is depicted as being powered by a battery in order to provide electrical isolation to the patient, it is possible to power the electrodes in other means, while still providing adequate electrical isolation, for example by inductively coupling the electrode to a remote power source.

As depicted, the differential amplifier 400 comprises a diode 424 in the feedback path 408 of the OP-AMP 102. The diode 424, and the inverting input of the OP-AMP 102 is coupled to a positive voltage supply (V+) 120 through a pull-up resistor 428. Similarly, a diode 426 in the feedback path 412 of the OP-AMP 104. The diode 426 and the inverting input of the OP-AMP 104 are coupled to a negative voltage supply (V−) 122 through a pull-down resistor 430. As will be appreciated, the two diodes are arranged in opposite directions so that a bias is introduced into the circuit. The circuit of differential amplifier 400 does not depend on balancing or matching any components, and the diodes used in each branch need not have similar characteristics nor do the resistors which source and sink current to or from them. All of these components only affect the value of the DC offset introduced into the amplifier, and as long as it is indeed a constant, the circuit will perform as required, and the resulting offset can simply be filtered away. It is noted that FIG. 4 does not depict the power connection of each of the OP-AMPs, however, they could be powered from the same voltage supply V+/V− used to provide the bias voltage for the LED.

It is contemplated that various component values may be selected for the various components of the circuit 400. However, in order to provide a concrete example, it is assumed that the, the resistor 116 is 200Ω, and the LED has a voltage drop of 2.0V. Each diode 424, 426 generates a voltage drop of 1.0V so that the bias voltage across the resistor 116 is 2.0V. It will be appreciated that the forward voltage drop across the diode is approximately constant regardless of the current through it, and as such, the selection of the pull-up and pull-down resistors is not critical. Further, it is assumed that the reference signal voltage (Vref) and the desired signal voltage (Vsig) vary from between −0.5V and +0.5V.

From the above assumptions, the LED bias current is 10 mA and the signal current in mA is 5(V_{sig}−V_{ref}). That is, the current through the LED will be 10+5(Vsig−Vref)mA. The forward voltage drop across each diode is 1.0V and is approximately constant regardless of the current. If the forward voltage drop of the diodes were completely independent of the current, the differential amplifier 400 would function as required. However, in practice the voltage drop across the diodes is not completely independent of the current when forward biased because of the resistive component of the diodes. If very low impedance diodes are chosen, the differential amplifier 400 circuit may be acceptable for many applications. In testing the circuit 400, the resistors feeding the diodes were selected to be different by an order of magnitude, and diodes with very different internal resistances and different forward voltage drops were used, however the circuit may still achieve a very reasonable CMRR, for example between −60 dB and −180 dB.

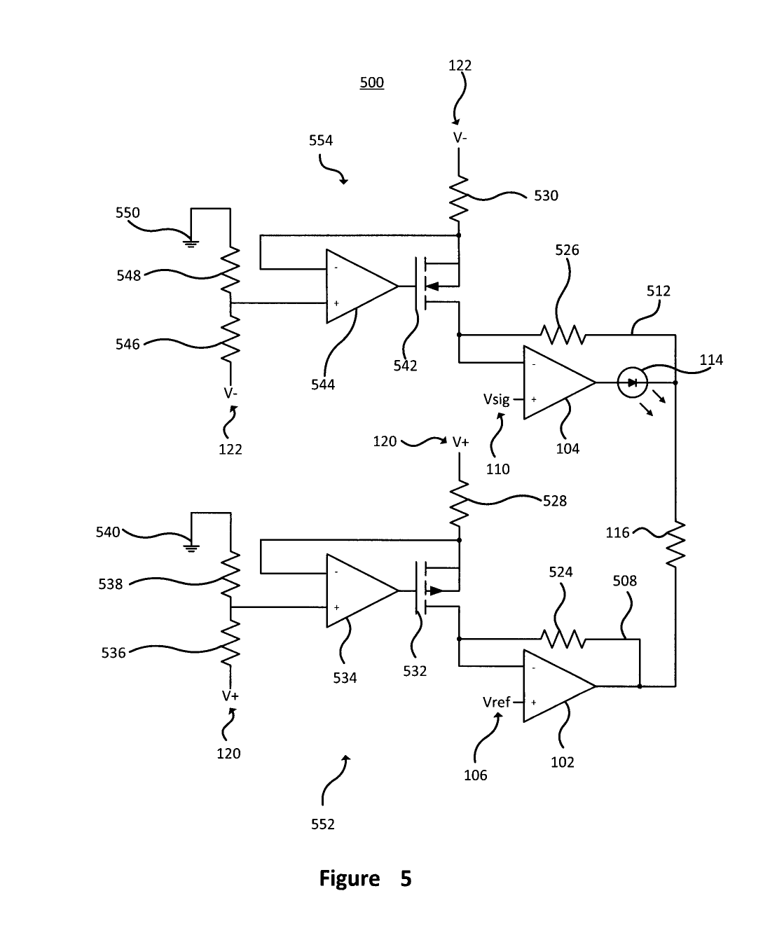

FIG. 5 depicts a schematic of a further embodiment of a differential amplifier for use in an electrode for measuring a biopotential. The differential amplifier 500 is substantially similar to the differential amplifier 400; however, instead of using diodes in the feedback path of the OP-AMPs to provide a bias voltage, the differential amplifier 500 utilizes resistors in the feedback paths driven by a respective constant current source or sink to generate the bias voltage. In this case, the amount of current sourced in conjunction with the corresponding resistor determines the voltage offset that will be added to Vsig. Likewise, the current flowing in the current sink in conjunction with the appropriate resistor determines the constant voltage that will be subtracted from Vref. Again, no component matching is necessary, since these values only serve to appropriately bias the LED. The amount of bias can be simply filtered out at the receiver, and only serves to keep the LED lit at all times so its variation in brightness can convey the biopotential information to the receiver.

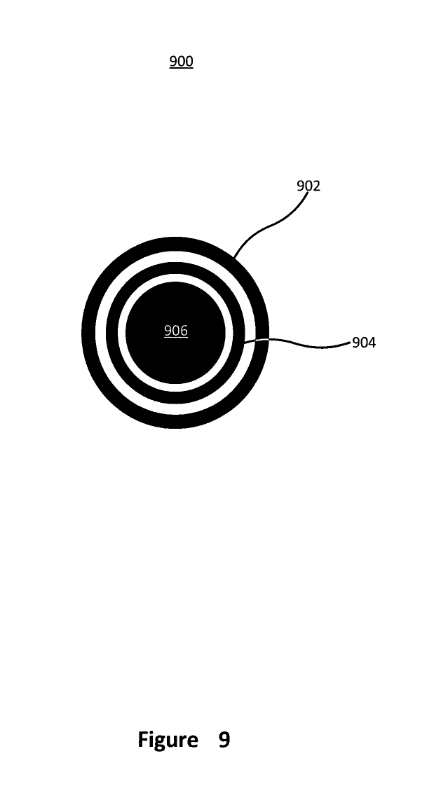

As depicted in FIG. 5 the OP-AMP 102 has a resistor 524 in the feedback path 508. The resistor provides a bias voltage that is added to the reference voltage (Vref) 106. It is noted that the resistor 524 is driven by a constant current sink 552, and as such produces a negative voltage drop across resistor 524. The constant current sink 552 comprises an OP-AMP 534 connected to the gate of a p-type field effect transistor (FET) 532. The drain of the FET 532 is connected to the inverting input of the OP-AMP 102 and the resistor 524 in the feedback path 508. The inverting input of the OP-AMP 534 is connected to the source of the FET 532, which is also connected to a pull-up resistor 528 connected to the positive voltage supply (V+) 120. The non-inverting input of the OP-AMP 534 is connected between a voltage divider comprising two resistors 536, 538 connected between the positive voltage supply (V+) and a ground reference 540. It is noted that, as described further with regards to FIGS. 8 and 9 the ground reference 540 is provided from a biasing voltage applied to a ground contact of the electrode, which is used bias the surface of the patient in the location of the electrode.

The OP-AMP 104 has a resistor 526 in the feedback path 512. The resistor 526 provides a bias voltage that is added to the desired voltage (Vsig) 110. It is noted that the resistor 526 is driven by a constant current source 552, and as such produces a positive voltage drop across the resistor 526. The constant current source 554 comprises an OP-AMP 544 connected to the gate of a n-type FET 542. The drain of the FET 542 is connected to the inverting input of the OP-AMP 104 and the resistor 526 in the feedback path 512. The inverting input of the OP-AMP 544 is connected to the source of the FET 542, which is also connected to a pull-down resistor 530 connected to the negative voltage supply (V−) 122. The non-inverting input of the OP-AMP 544 is connected between a voltage divider comprising two resistors 546, 548 connected between the negative voltage supply (V+) and the ground reference 550.

For the differential amplifier circuit of FIG. 5 to work as prescribed, the current source 554 and current sink 552 should be constant and independent of the current flowing in other parts of the circuit. Although constant current sources and sinks are designed to deliver constant currents, the outputs of the final OP-AMP of a constant current source/sink will exert some influence creating tiny changes to these currents which could potentially cause the differential amplifier 500 to have unacceptable performance for certain applications. To enhance the circuit even further, the feedback resistors 524, 526 used in the feedback paths of differential amplifier 500 may be replaced with diodes 424, 426 in the feedback path as described with regards to the differential amplifier 400 of FIG. 4

It is contemplated that various component values may be selected for the various components of the circuit 500. However, in order to provide a concrete example, it is assumed that the, the resistor 116 is 200Ω, and the LED has a voltage drop of 2.0V. Each resistor 524, 526 generates a voltage drop of 1.0V so that the bias voltage across the resistor 116 is 2.0V. The resistors 524, 526 are selected to be 50Ω and as such, the current flowing through them, provided by the respective current source or sink should be 20 μA to provide the 1V drop. Further, it is assumed that the reference signal voltage (Vref) and the desired signal voltage (Vsig) vary from between −0.5V and +0.5V. The pull-up and pull-down resistors 528, 530 may be 100 kΩ. The resistors 548, 538 of the voltage dividers may be 100 kΩ and the resistors 536, 546 of the voltage dividers may be 200 kΩ, to provide 1 V and −1 V at the non-inverting inputs of the current source/sink's OP-AMP 534, 536. The negative supply voltage may be −3V and the positive supply voltage may be +3V. From the above assumptions, the LED bias current is 10 mA and the signal current is 5(V_{sig}−V_{ref}). The LED current expressed in mA is therefore 10+5(Vsig−Vref).

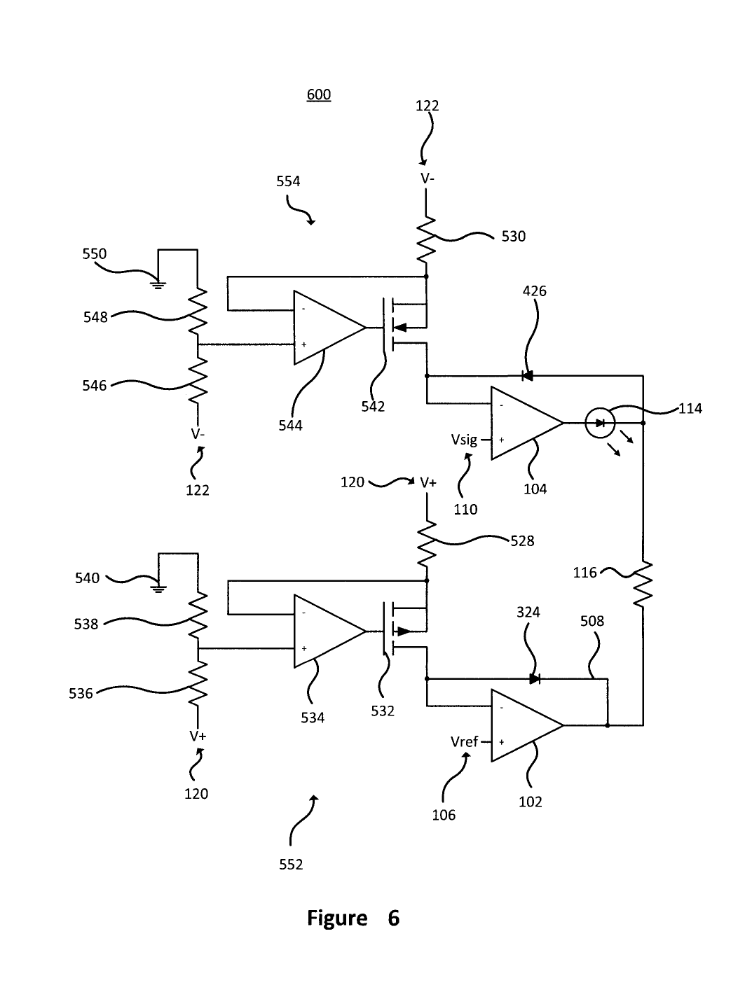

FIG. 6 depicts a schematic of a further embodiment of a differential amplifier for use in an electrode for measuring a biopotential. The differential amplifier 600 is substantially similar to the differential amplifier 500 described above; however, the resistors 524, 526 in the feedback paths 508, 512 are replaced by diodes 424, 426 as describe above with regards to FIG. 4 The operation is substantially similar as described above; however, the use of the diode driven by the constant current source or sink provides a bias signal that has greater independence on the current than the embodiments described above.

It is contemplated that various component values may be selected for the various components of the circuit 400. However, in order to provide a concrete example, it is assumed that the, the resistor 116 is 200Ω, and the LED has a voltage drop of 2.0V. Each diode 424, 426 generates a voltage drop of 1.0V so that the bias voltage across the resistor 116 is 2.0V. The current through the diodes may be 20 μA provided by the respective current source or sink. Further, it is assumed that the reference signal voltage (Vref) and the desired signal voltage (Vsig) vary from between −0.5V and +0.5V. The pull-up and pull-down resistors 528, 530 may be 100 kΩ. The resistors 548, 538 of the voltage dividers may be 100 kΩ and the resistors 536, 546 of the voltage dividers may be 200 kΩ, to provide 1 V and −1 V at the non-inverting inputs of the current source/sink's OP-AMP 534, 536. The negative supply voltage may be −3V and the positive supply voltage may be +3V. From the above assumptions, the LED bias current is 10 mA and the signal current is 5(V_{sig}−V_{ref}). The LED current expressed in mA is therefore 10+5(Vsig−Vref).

The embodiments of the differential amplifiers 100, 200, 400, 500, 600 described above were tested and shown to produce the difference of the signal and reference voltages when tested without large common mode components. The differential amplifiers 100, 200, 300, 400, 500, 600 were tested in a simulator in order to determine the CMRR of each of the embodiments. It is noted that since the CMRR of the differential amplifiers does not rely upon a precise matching of component values, the simulation results may be expected to provide a good indication as to the CMRR of the physical circuits. The various implementations exhibited a CMRR of at least approximately −127 dB.

It will be appreciated that various arrangements and component values may produce different values for the CMRR. For example, the differential amplifier 300 described above with reference to FIG. 3 was tested in a simulator with a resistor of 85Ω and a 1 V battery. The simulated differential amplifier was found to have an extremely high CMRR of approximately −320 dB.

The differential amplifiers described above accurately determine the difference between the desired signal and reference signal voltages. The result is scaled by a constant by virtue of the fact that the original signal is converted into light and back into electricity in the measuring process. Prior to the signal being converted to light, the common mode components are cancelled out. It is noted that although there may be uncertainty in the scaling factor between the biopotential signal and the final generated signal; the scaling factor is a constant, and subsequent amplification may be, easily and not critically, calibrated appropriately to account for it. Further, the measurement of biopotentials in EEG are generally more concerned with relative changes in the EEG within longer windows of time or with respect to some baseline, and so in most applications, precise scaling of the signal is not a major concern.

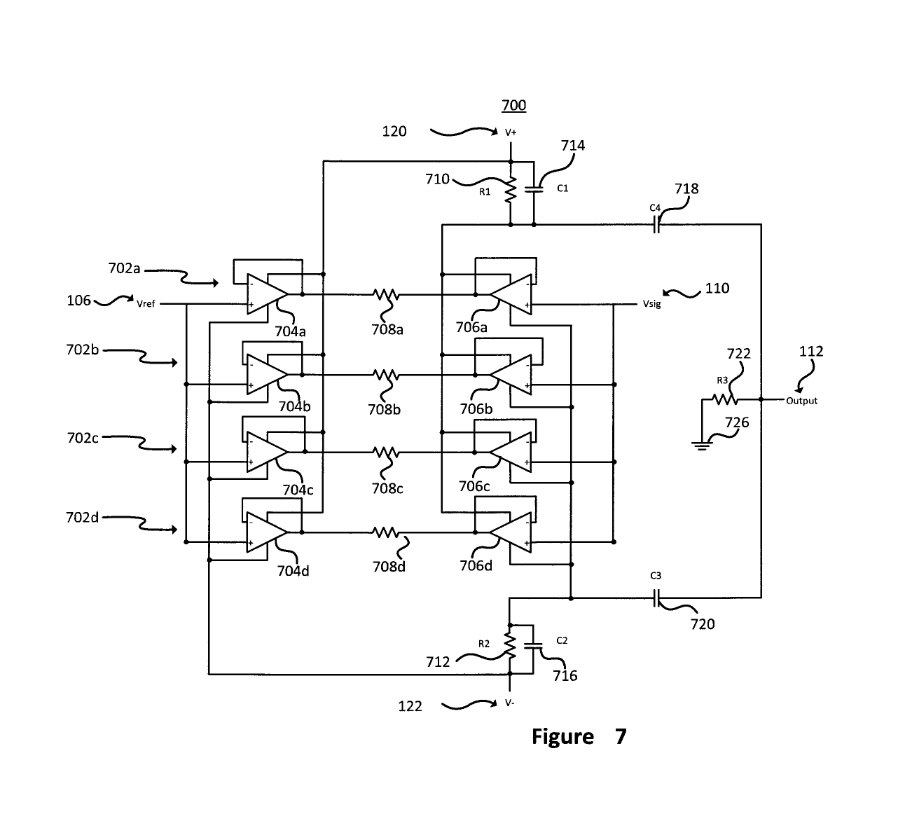

FIG. 7 depicts a schematic of an embodiment of a multi-sample differential amplifier for use in an electrode for measuring a biopotential. The differential amplifiers 100, 200, 400, 500, 600 described above provide a single differential amplifier for measuring the desired signal. The individual differential amplifier comprises the two OP-AMPs with their outputs coupled together through the resistor. In the differential amplifiers 100, 200, 400, 500, 600 described above, an output LED is coupled between the OP-AMP outputs as well. A biasing component is included in the differential amplifiers 100, 200, 400, 500, 600 described above, in order to provide a bias current to the LED.

The multi-sample amplifier 700 is similar to the differential amplifiers described above; however, it is composed of a plurality of parallel individual differential amplifiers 702a, 702b, 702c, 702d, each of which is similar in functionality to the individual differential amplifiers described above. The multi-sample amplifier 700 does not include an output LED coupled between the outputs of the OP-AMPs of the individual differential amplifiers 702a, 702b, 702c, 702d, and as such, there is no need to provide a biasing component to each individual differential amplifier.

As depicted, the multi-sample differential amplifier 700 comprises a plurality of individual parallel differential amplifiers 702a, 702b, 702c, 702d. Each of the individual differential amplifiers comprises two OP-AMPs, with one of the OP-AMPs 704a, 704b, 704c, 704d having an input connected to the reference signal 106 and the other input connected to the output of the respective OP-AMP 704a, 704b, 704c, 704d. The other OP-AMPs 706a, 706b, 706c, 706d have one input connected to a desired signal no and the other input connected to the output of the respective OP-AMP 706a, 706b, 706c, 706d. Each of the differential amplifiers 702a, 702b, 702c, 702d has a resistor coupled between the outputs of the respective OP-AMPs. Each of the OP-AMPs 704a, 704b, 704c, 704d, 706a, 706b, 706c, 706d has a high and low power supply rail for either sourcing or sinking current to or from the output.

Each of the OP-AMPs 704a, 704b, 704c, 704d connected to the reference signal have their power supply rails connected to the positive voltage supply (V+) 120 and the negative voltage supply (V−) 122. Similarly, each of the OP-AMPs 706a, 706b, 706c, 706d connected to the desired signal 112 have their power supply rails coupled to the positive voltage supply (V+) 120 and the negative voltage supply (V−) 122. However, the OP-AMPs 706a, 706b, 706c, 706d connected to the desired signal 112 have their power supply rails coupled through a pull-up resistor 710 and a pull-down resistor 712. As will be appreciated, the current flowing through the individual resistors 708a, 708b, 708c, 708d will be sourced/sinked from/to the power supply V+/V−, and as such will also flow through the pull-up and pull-down resistors. As such, a voltage across the pull-up and pull-down resistors may be used as an output signal that is proportional to the desired signal, with the common noise removed.

The individual differential amplifiers 702a, 702b, 702c, 702d function similar to the differential amplifiers 100, 200, 400, 500, 600 described above. That is, the current through each of the resistors 708a, 708b, 708c, 708d is proportional to the difference signal between the reference signal 106 and the desired signal 112. Although each individual differential amplifier has a very high CMRR 702a, 702b, 702c, 702d; the OP-AMPS may introduce stochastic random noise into the output. Since each individual differential amplifier measures the same signal, adding the output of the individual differential amplifiers together tends to cancel out the random noise, while adding the desired signals together constructively. As such, the sum of the currents passing through the individual resistors can be used to provide a signal that is proportional to the difference between the reference signal and the desired signal, while removing a portion of random noise introduced into the output signal by the OP-AMPs.

One way to measure the sum of the current through the series resistors 708a, 708b, 708c, 708d, is to monitor the current flowing to the OP-AMPs on one side, such as OP-AMPs 706a, 706b, 706c, 706d as depicted, although it is contemplated that the current flowing through the other OP-AMPs could be measured. At any point in time, an OP-AMP's output is either sourcing current, sinking current, or neither. In the first case, the sourced current comes from the positive power supply rail (V+) 120. In the second case, the negative rail (V−) 122 functions to sink the current. In the third case, the only current is the quiescent current which flows from positive to negative rail at all times and creates an increase in the source or sink current which acts as an offset to those values. As such, the current flowing through the power supply rails of one of the chains of OP-AMPs is proportional to the difference signal plus a small offset from the quiescent current.

Two low valued resistors 710, 712 are placed between the OP-AMPs 706a, 706b, 706c, 706d supply rails and the high and low power rails 120, 122. The voltage developed across these resistors 710, 712 provides an output signal proportional to the signal being measured, with the common mode signal rejected. The voltage across the two resistors is proportional to the current drawn from the OP-AMPs. By using the voltage across the resistors as an output signal, the resistance will effectively scale the current drawn from the OP-AMPs, and as such, it is desirable to select the resistors' values to be as large as practical. However, the values of the resistors must be selected so that the voltages supplied to the power supply rails of the OP-AMPs will remain within the operating ranges of OP-AMPs.

Because the positive and negative currents are measured by separate resistors, the result is a variation of a push-pull amplifier, and the only requirement of balancing component values, is to maintain a reasonable amount of symmetry between “push” and “pull”. The differential amplification is not affected by the selection of these components, and therefore they do not need to be critically matched.

It is only necessary to monitor the current in one half of the individual differential amplifiers, not both. Therefore, half the unity-gain amps are fed directly from the power supply V+/V− while the other half are all fed through the measurement resistors 710, 712 on the positive and negative rails. Since all stages draw power through these same two resistors, the stochastic internally generated noise in each OP-AMP combine to tend towards zero while the signal activity being similar combines to reinforce. Therefore the signal to noise ratio (SNR) is improved by a factor of the square root of the number of individual differential amplifiers used in parallel compared to a single differential amplifier implementation. Although only four individual differential amplifiers 702a, 702b, 702c, 702d are depicted, it is contemplated that more can be used, for example 6, 8, 10, 12 or more.

The multi-sample differential amplifier 700 is depicted as including filter capacitors 714, 716 for filtering the power supply V+/V−. The output coupling is via capacitors 718, 720 and a resistor 722 connected to a ground reference 726, which together form a low-pass filter to immediately remove the DC offset from the output.

It is contemplated that various component values may be selected for the various components of the circuit 700. However, in order to provide a concrete example, it is assumed that the, the resistors 708a, 708b, 708c, 708d between each of the OP-AMPs are 680Ω. The pull-up and pull-down resistors 710, 712 are 1 kΩ, and the filter capacitors 714, 716 are 0.1 μF The capacitors 718, 720 may be 0.1 μF and the resistor 722 may be 4MΩ. Further, it is assumed that the reference signal voltage (Vref) and the desired signal voltage (Vsig) vary from between −0.5V and +0.5V.

The current through each of the individual differential amplifiers as a result of the differential voltage results in four independent currents, which add together to form the current through the 1K resistors 710, 712 on the supply lines. A given differential voltage is then amplified by 1K/(680/4) or 1000/170 or 5.88. It is noted however, that the push-pull design means that one coupling capacitor 718, 720 is “dead weight” whenever the other is trying to couple through a voltage resulting in only 50% of this amplification actually reaching the output. Therefore, the net gain becomes 2.94 instead.

It is possible to add a voltage offset into each of the individual differential amplifiers of the multi-sample differential amplifier 700 as described above to guarantee that the differential voltage would always be strictly positive so that two improvements could result. First, the gain would double for the same component selection, and second, the “push-pull” element would vanish eliminating any concern about asymmetry in positive versus negative differential values.

FIG. 8 depicts a schematic of components of an electrode for use in measuring a biopotential. The electrode 800 utilizes the multi-sample differential amplifier 700 described above and as such its operation is not described in further detail. In addition to the multi-sample differential amplifier 700, the electrode 800 comprises an output section for converting the output signal from the multi-sample differential amplifier into an optical signal that can be communicated to a remote location for further processing via a fiber optic cable.

The electrode is powered by a single cell battery, and as such there is no ‘center tap’ from the battery to provide a ground reference. As such, an OP-AMP 802 is used to drive the ground reference. The output of the OP-AMP 802 is connected at the ground reference which is connected by a feedback path to an input of the OP-AMP 802. The other input of the OP-AMP is connected in the middle of a voltage divider comprising two resistors 804, 806 serially connected between the supply rails V+ 120, V− 122.

As described, the OP-AMP 802 uses a voltage divider to “split” the supply voltage which it uses as a reference to generate the correct ground potential. The values of resistors 804, 806 may be selected such that the “ground” is not midway between the supply rails V+/V−. The reason for this is that the voltage supplied by the battery is limited, and the LED should be forward biased by about 2 volts. The use of the unequal voltage divider to drive the ground reference provides a sufficient “cushion” to ensure that the output of the OP-AMP driving the LED will be sufficiently higher than the working voltage of the signal to be conveyed so that the LED will provide an appropriate light intensity based on the difference signal at all times.

The output section comprises two non-unity gain OP-AMPs 808, 810 connected between the ground reference 726 and the high supply voltage V+ 120 for amplifying the small difference signal output from the multi-sample differential amplifier 700 to a level sufficient to drive the LED. The output of the second OP-AMP 810 is coupled to the input of a unity gain amplifier used to drive the output LED 814. The output of the OP-AMP 812 is connected to the LED 814. The other end of the LED is connected to the input of the OP-AMP 812, providing a feedback path, as well as to a resistor 816 connected to the low power supply V− 122. The voltage across the resistor 816 will be equal to the amplified difference signal output by OP-AMP 810 plus the offset ground reference. As such, the current flowing through the LED 814 will be proportional to the difference signal plus a constant offset value.

As described above, the ground is set to be above the negative rail V− 122. If the ground reference is chosen, by appropriate selection of resistors' 804, 806 values, to be 1 volt above the negative rail, the signal range may be considered to be +/−1 V with respect to ground, while allowing the LED to always be 2 volts higher than the maximum signal voltage so that it would never have to glow darker than “black” to correctly communicate a light level proportional to the signal voltage into the fiber.

FIG. 9 depicts a schematic of contact areas of an electrode for measuring a biopotential. The contact areas are a portion of the electrode that actually contacts the patient's skin to measure the biopotential signals. The contact areas comprise two concentric contact areas 902, 904 containing a solid central contact area 906. The solid central contact area 906 captures the desired signal (Vsig) 110. The inner concentric contact area 904 provides the reference signal (Vref) 106, and the outer concentric contact area 902 functions as a ground connection to bias the scalp in the area of the electrode that may be driven by OP-AMP 902 described above with reference to FIG. 8

Normally it would not be possible to provide a ground ring in this way, because all such ground rings would connect together at a remote amplifier forcing all such ringed regions over the entire scalp to one fix potential creating an “iso-potential” which would then distort the real brain activity on the scalp. However, every electrode is completely electrically isolated from each other and battery powered with only a fiber optic cable coming from the electrode, and therefore the ground ring only creates a local iso-potential which does not interfere with the measurement of the biopotentials in the area.

The outer concentric contact patch 902 may have an outer radius of approximately 0.5000″ and an inner radius of approximately 0.4472″. The outer concentric contact patch 902 may be separated from the inner concentric contact patch 904 by approximately 0.0599″. The inner concentric contact patch 904 may have an outer radius of approximately 0.3873″ and an inner radius of approximately 0.3162″. The inner concentric contact area 904 may be separated from the inner solid contact area 906 by approximately 0.0926″. The solid contact patch 906 may have a radius of approximately 0.2236″.

It is contemplated that other dimensions of the contact areas are possible. However with the dimensions described above, the contact areas 902, 904, 906 and the spaces between them each occupy the same area. This is beneficial for the central contact area 906 and the inner concentric contact area 904 to help ensure the impedance of each is matched.

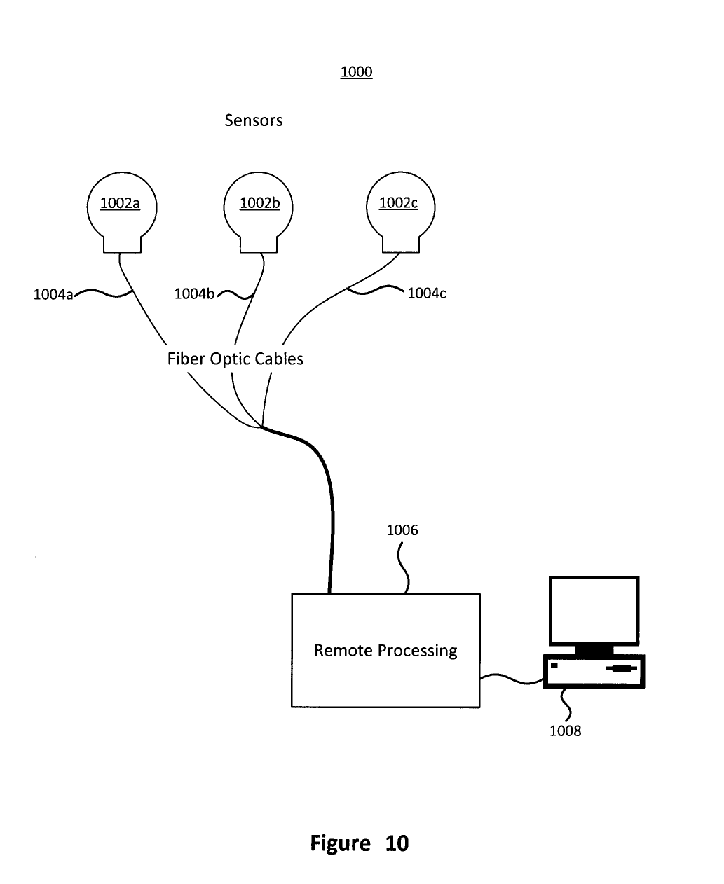

FIG. 10 depicts in a block diagram a system for measuring biopotentials. As depicted the system comprises a plurality of electrodes 1002a, 1002b, 1002c (referred to collectively as electrodes 1002). The electrodes 1002 may comprise a differential amplifier as described with regards to the single differential amplifiers 100, 200, 400, 500, 600, or the multi-sample differential amplifier 700. The electrodes are intended for placing on a patient's body, such as their scalp, to measure a local biopotential. The electrodes 1002 are depicted as being coupled to a remote processor via respective fiber optic cables 1004a, 1004b, 1004c, although it is contemplated that the measured signals may be transmitted to the remote processor via other means, such as through a wireless interface. The remote processor 1006 may include photo detectors that receive respective optical signals from the electrodes and converts the optical signals to corresponding electrical signals. The remote processor 1006 may further provide additional amplification and filtering of the converted signals. The remote processor 1006 may be connected to a computer or computer system 1008 for further processing the signals for analysis, recording and display.

Various embodiments of differential amplifiers and electrodes having differential amplifiers have been described. The above-described embodiments of the invention are intended to be examples of the present invention and alterations and modifications may be effected thereto, by those of ordinary skill in the art, without departing from the scope of the invention which is defined solely by the claims appended hereto.

1. An apparatus for measuring potentials on a body surface comprising:
a first contact area for contacting the body surface and providing a first signal;
a second contact area for contacting the body surface and providing a second signal;
a differential amplifier for providing an output signal proportional to the difference between the first signal and the second signal, the differential amplifier comprising:
a first OP-AMP having a first input, second input and an output, the first input coupled to the first signal and the second input coupled to the output;
a second OP-AMP having a first input, second input and an output, the first input coupled to the second signal and the second input coupled to the output; and
a resistor connected between the output of the first OP-AMP and the output of the second OP-AMP,
wherein the output signal is proportional to the current through the resistor.

2. The apparatus of claim 1, further comprising a plurality of differential amplifiers for providing the output signal, each of the differential amplifiers comprising:
a first OP-AMP having a first input, second input and an output, the first input coupled to the first signal and the second input coupled to the output;
a second OP-AMP having a first input, second input and an output, the first input coupled to the second signal and the second input coupled to the output; and
a resistor connected between the output of the first OP-AMP and the output of the second OP-AMP,
wherein the output signal is proportional to a summation of the current through each of the resistors of the plurality of differential amplifiers.

3. The apparatus of claim 2, wherein each of the first and second OP-AMPs of the plurality of differential amplifiers comprise a respective positive supply rail and a respective negative supply rail, the apparatus further comprising:
a power supply having a positive rail and negative rail;
a high-side resistor connected between the positive supply rails of the first OP-AMPs and the positive rail of the power supply; and
a low-side resistor connected between the negative supply rails of the first OP-AMPs and the negative rail of the power supply,
wherein the output signal is provided by the current through the high-side resistor and the low-side resistor and is proportional to the summation of the current through each of the resistors of the plurality of differential amplifiers.

4. The apparatus of claim 3, further comprising:
an output resistor coupled between a ground reference and an output node, the output node coupling a high-side of the low-side resistor to a low-side of the high-side resistor.

5. The apparatus of claim 4, further comprising:
a third contact area for contacting the body surface and providing the ground reference, the third contact area biasing a portion of the body surface in the vicinity of the apparatus to a bias voltage.

6. The apparatus of claim 5, wherein:
the first contact area comprises a circle and provides a desired signal;
the second contact area is a concentric ring and provides a reference signal; and
the third contact area is a larger concentric ring and provides the ground reference signal.

7. The apparatus of claim 1, further comprising:
an output interface for communicating the output signal to a remote location.

8. The apparatus of claim 7, wherein the output interface comprises a light emitting diode (LED) providing the output signal to the remote location over a fiber optic connection.

9. The apparatus of claim 8, wherein the LED is located between the output of the first OP-AMP and the resistor, and wherein the output of the first OP-AMP is coupled to the second input between the LED and the resistor.

10. The apparatus of claim 1, further comprising a battery coupled between the resistor and the second OP-AMP for providing a biasing voltage.

11. The apparatus of claim 1, further comprising a biasing component in a feedback path of each of the OP-AMPs to provide a biasing voltage across the resistor, wherein the biasing component comprises one of:
a battery;
a diode coupled to a pull-up or pull-down resistor to provide a voltage drop across the diode;
a resistor coupled to a constant current source to provide a voltage drop across the resistor; and
a diode coupled to a constant current source to provide a voltage drop across the resistor.

12. (canceled)

13. The apparatus of claim 1, wherein the first signal comprises a desired biopotential signal and the second signal comprises a reference biopotential signal.

14. A system for measuring biopotentials of a patient, the system comprising:
a plurality of apparatuses for measuring biopotentials as claimed in claim 1; and
a remote processing unit configured to (i) receive signals corresponding to the output signals of respective apparatuses of the plurality of apparatuses, and (ii) process the received signals.

15. The system of claim 14, wherein each of the apparatuses are coupled to the remote processing unit by a respective fiber optic cable, wherein, the remote processing unit comprises a plurality of photo detectors each coupled to a respective fiber optic cable for converting an optical signal to an electrical signal.

16. The system of claim 14, wherein the remote processing unit amplifies and filters the received signals corresponding to the output signals of the respective apparatuses.

17. The system of claim 14, wherein the remote processing unit further comprises a computing device for recording and displaying the received signals corresponding to the output signals.

18. The system of claim 14, wherein the apparatuses are used to measure brain activity for an electroencephalogram (EEG).

19. A differential amplifier for providing an output signal proportional to a difference between a first signal and a second signal, the differential amplifier comprising at least one individual differential amplifiers comprising:
a first OP-AMP having a first input, second input and an output, the first input coupled to the first signal and the second input coupled to the output;
a second OP-AMP having a first input, second input and an output, the first input coupled to the second signal and the second input coupled to the output; and
a resistor connected between the output of the first OP-AMP and the output of the second OP-AMP,
wherein the output signal is proportional to the current through the resistor.

20. The differential amplifier of claim 19, further comprising a plurality of individual differential amplifiers, each comprising:
a first OP-AMP having a first input, second input and an output, the first input coupled to the first signal and the second input coupled to the output;
a second OP-AMP having a first input, second input and an output, the first input coupled to the second signal and the second input coupled to the output; and
a resistor connected between the output of the first OP-AMP and the output of the second OP-AMP,
wherein the output signal is proportional to a summation of the current through each of the resistors of the plurality of channels of the differential amplifier.

21. The differential amplifier of claim 20, wherein each of the first and second OP-AMPs of the plurality of individual differential amplifiers comprise a respective positive supply rail and a respective negative supply rail, the apparatus further comprising:
a power supply having a positive rail and negative rail;
a high-side resistor connected between the positive supply rails of the first OP-AMPs and the positive rail of the power supply; and
a low-side resistor connected between the negative supply rails of the first OP-AMPs and the negative rail of the power supply,
wherein the output signal is provided by the current through the high-side resistor and the low-side resistor and is proportional to the summation of the current through each of the resistors of the plurality of differential amplifiers.

22. The differential amplifier of claim 19, further comprising a battery coupled between the resistor and the second OP-AMP for providing a biasing voltage.

23. The differential amplifier of claim 19, further comprising a biasing component in a feedback path of each of the OP-AMPs to provide a biasing voltage across the resistor, wherein the biasing component comprises one of:
a battery;
a diode coupled to a pull-up or pull-down resistor to provide a voltage drop across the diode;
a resistor coupled to a constant current source to provide a voltage drop across the resistor; and
a diode coupled to a constant current source to provide a voltage drop across the resistor.

24. (canceled)
